(19) United States
(12) Patent Application Publication
(10) Pub. No.: US 2015/0035163 A1
(43) Pub. Date: Feb. 5, 2015

(54) SEMICONDUCTOR PACKAGE AND METHOD OF FABRICATING THE SAME

(71) Applicant: Siliconware Precision Industries Co., Ltd., Taichung (TW)

(72) Inventors: Guang-Hwa Ma, Taichung (TW); Shih-Kuang Chiu, Taichung (TW); Shih-Ching Chen, Taichung (TW); Chun-Chi Ke, Taichung (TW); Chang-Lun Lu, Taichung (TW); Chun-Hung Lu, Taichung (TW); Hsien-Wen Chen, Taichung (TW); Chun-Tang Lin, Taichung (TW); Yi-Che Lai, Taichung (TW); Chi-Hsin Chiu, Taichung (TW); Wen-Tsung Tseng, Taichung (TW); Tsung-Te Yuan, Taichung (TW); Lu-Yi Chen, Taichung (TW); Mao-Hua Yeh, Taichung (TW)

(73) Assignee: SILICONWARE PRECISION INDUSTRIES CO., LTD., Taichung (TW)

(21) Appl. No.: 14/012,402

(22) Filed: Aug. 28, 2013

(30) Foreign Application Priority Data
Aug. 2, 2013 (TW) 102127331

(51) Int. Cl. H01L 23/538; H01L 23/00

(52) U.S. Cl. CPC H01L 23/5384; H01L 24/96
USPC 257/774; 438/113

(57) ABSTRACT

The present invention provides a semiconductor package and a method of fabricating the same, including: placing a semiconductor element in a groove of a carrier; forming a dielectric layer on the semiconductor element; forming on the dielectric layer a circuit layer electrically connected to the semiconductor element; and removing a first portion of the carrier below the groove to keep a second of the carrier on a sidewall of the groove intact for the second portion to function as a supporting part. The present invention does not require formation of a silicon interposer, therefore the overall cost of the final product is much reduced.

### BACKGROUND OF THE INVENTION

1. Field of the Invention

The present invention relates to semiconductor packages and a method of fabricating the same, and, more particularly, to a semiconductor package having wafer level circuits and a method of fabricating the same.

2. Description of the Prior Art

As the technology for developing electronic products is steadily growing, electronic products have now moved to multi-functionality and high functionality. The semiconductor packaging technology has been widely used nowadays to chip scale package (CSP), Direct Chip Attached (DCA), Multi Chip Module (MCM), and 3D-IC stacking technology.

FIG. 1 is a schematic cross-sectional view of a conventional semiconductor package, wherein a through silicon interposer (TSI) 10 is formed between a substrate 18 and a semiconductor chip 11. The TSI 10 has through-silicon vias (TSV) 100 and a redistribution layer (RDL) 15 formed on the through-silicon vias (TSV) 100, allowing the redistribution layer 15 through each of the plurality of conductive elements 17 to be electrically connected with solder pads 180 on the substrate 18. The spacing distance between any two of the solder pads 180 is greater than that of the conductive elements 17. The conductive elements 17 are covered by an adhesive material, and the electrode pads 110 of the semiconductor chip 11 are electrically connected to the through-silicon via (TSV) 100 through a plurality of solder bumps 19. An adhesive material is then applied to cover the solder bumps 19.

If the semiconductor chip 11 is directly attached to the substrate 18, since the heat expansion coefficient difference between the smaller semiconductor chip and the larger circuit substrate is rather large, it is difficult to establish a good bonding between the solder bumps 19 on the periphery of the chip 11 and the corresponding solder pads 180, causing the solder bumps 19 to be easily detached from the substrate 18. In addition, due to problems associated with thermal stress and warpage as a result of mismatch of heat expansion coefficient between semiconductor chip and substrate, the reliability between the semiconductor chip and the substrate is decreased causing frequent failures in reliability test.

Accordingly, by providing he interposer 10 made of silicon fabricating process of the semiconductor substrate, since the material thereof is similar to the semiconductor chip 11, the conventional problems can be solved.

The only concern in the foregoing fabricating method of the semiconductor package 1 is the fabrication cost of the through-silicon via (TSV) 100 in the silicon interposer 10, which includes forming the via and the metal underfill process. The total cost of the through-silicon via (TSV) 100 is 40-50% of the total cost in the fabricating process. Hence, it is difficult to reduce the overall cost.

Moreover, the technical difficulty in fabricating the silicon interposer 10 is high. Hence, under the same fabricating cost, the yield of the semiconductor package 1 is relatively low.

Therefore, there is an urgent need in solving the foregoing problems.

### SUMMARY OF THE INVENTION

In light of the foregoing drawbacks of the prior art, the present invention proposes a semiconductor package, comprising: a semiconductor element having opposing active and non-active surfaces; a dielectric layer formed on the active surface of the semi element; and a circuit layer formed on the dielectric layer and electrically connected to the semiconductor element.

In an embodiment, the semiconductor element further comprises side surfaces abutting the active surface and the non-active surface. The dielectric layer covers a periphery of the side surfaces of the semiconductor element. The dielectric layer is made of a non-organic material or an organic material. The dielectric layer comprises a supporting part surrounding the dielectric layer.

In an embodiment, the semiconductor package further comprises an etch-stop layer such as silicon nitride and an opening to expose the semiconductor element, covered by the a dielectric material made of a non-organic material or an organic material, allowing the etch-stop layer to be formed between the active surface of the semiconductor element and the dielectric layer. The dielectric material further comprises a supporting part.

In an embodiment, the supporting part is a silicon-containing frame, and the thickness of the semiconductor element can be greater than or not greater than the height of the supporting part.

The present invention further proposes a method of fabricating a semiconductor package, comprising: placing in a groove of a carrier a semiconductor element having opposing active and non-active surfaces; forming a dielectric layer on the active surface of the semiconductor element; forming on the dielectric layer a circuit layer electrically connected to the semiconductor element; and removing a first portion of the carrier below the groove to keep a second of the carrier on a sidewall of the groove intact for the second portion to function as a supporting part.

In an embodiment, the carrier is a silicon-containing board. In an embodiment, the carrier has a plurality grooves, a singulation process is performed after the first portion of the carrier below the groove is removed, and the supporting part is also removed during the singulation.

In an embodiment, the semiconductor element protrudes or does not protrude from the groove.

In an embodiment, through the non-active surface, the semiconductor element is assembled in the groove via a bonding layer. The bonding layer is between 5 to 25 μm in thickness, and is removed when the first portion of the carrier below the groove.

In an embodiment, the groove is filled with a dielectric layer. The semiconductor element further comprises side surfaces abutting the active surface and the non-active surface. The dielectric layer covers the periphery of the side surfaces of the semiconductor element and is made of a non-organic or an organic material.

In an embodiment, the method further comprises forming an etch-stop layer on the active surface of the semiconductor element, allowing the dielectric layer to be formed on the etch-stop layer. For example, before the etch-stop layer is formed, a dielectric material is formed in the groove to cover the semiconductor element, then an opening is formed on the dielectric layer to expose the active surface of the semiconductor element, allowing the etch-stop layer to be formed on the active surface of the semiconductor element. The etch-stop layer is made of silicon nitride, and the dielectric material is an organic material or a non-organic material.

In an embodiment, the semiconductor element is a multi-chip module or a single-chip package.

In an embodiment, the thickness of the semiconductor element is between 10 to 300 μm.

In an embodiment, the dielectric layer and the adhesive material are made of different materials, and the dielectric layer is made of an organic material or a non-organic material.

In an embodiment, the circuit layer has a plurality of conductive vias for being electrically connected with the semiconductor element.

In an embodiment, the method further comprises forming redistribution layer on the dielectric layer and the circuit layer. The redistribution layer is electrically connected with the circuit layer. After the first portion of the carrier below the groove is removed, the substrate is attached on and electrically connected to the redistribution layer. In an embodiment, the redistribution layer comprises stacked dielectric layer and circuit part and the dielectric part is made of an organic material or a non-organic material.

In an embodiment, the method further comprises attaching and electrically connecting a substrate onto the circuit layer after the first portion of the carrier below the groove is removed.

In an embodiment, the method further comprises forming an etch-stop layer on the active surface of the semiconductor element before forming the dielectric layer, allowing the dielectric layer to be formed on the etch-stop layer. For example, before the etch-stop layer is formed, a dielectric material is formed on the adhesive material and the active surface of the semiconductor element, covering the side surfaces of the semiconductor element. Then an opening is formed on the dielectric material to expose the active surface of the semiconductor element, allowing the etch-stop layer to be formed on the act e surface of the semiconductor element. In an embodiment, the etch-stop layer is made of silicon nitride, and the dielectric material is made of an organic material or a non-organic material.

In an embodiment, the non-organic material is silicon oxide (SiO₂) or silicon nitride (SiₓN_{y}), and the organic material is Polyimide (PI), Polybenzoxazole (PBO), or Benzocyclclobutene (BCB).

Accordingly, in a semiconductor package and a method of fabricating the same according to the present invention, it is no longer required to have a conventional silicon interposer, as a result the overall fabricating cost is significantly reduced, and the fabricating process is simplified, ensuring the productivity and yield of the final semiconductor package to be significantly improved.

### BRIEF DESCRIPTION OF THE DRAWINGS

The present invention can be more fully understood by reading the following detailed description of the preferred embodiments, with reference made to the accompanying drawings, wherein:

FIG. 1 is a schematic cross-sectional view of a conventional semiconductor package;

FIGS. 2A-2H are schematic cross-sectional views of a semiconductor package in accordance with a first embodiment of the present invention, wherein FIGS. 2B′ and 2B″ represent other embodiments of FIG. 2B, FIGS. 2G° and 2G″ represent other embodiments of FIG. 2G, and FIGS. 2H′ and 2H″ represent other embodiments of FIG. 2H.

FIGS. 3A-3E are schematic cross-sectional views of a semiconductor package in accordance with a second embodiment of the present invention, wherein FIGS. 3C′ and 3C″ represent other embodiments of FIG. 3C, and FIGS. 3E′ and 3E″ represent other embodiments of FIG. 3E.

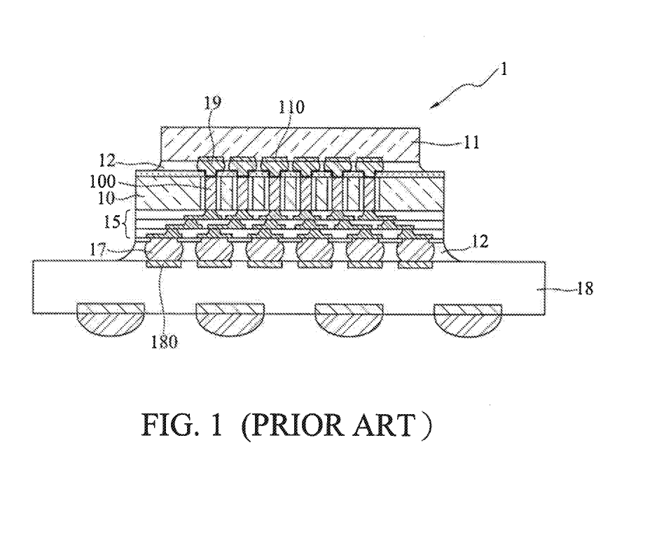

### DETAILED DESCRIPTION OF THE PREFERRED EMBODIMENTS

The present invention is described in the following with specific embodiments, an that one skilled in the pertinent art can easily understand other advantages and effects of the present invention from the disclosure of the present invention.

It is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements. In addition, words such as “on”, “top” and “a” are used to explain the preferred embodiment of the present invention only and should not limit the scope of the present invention.

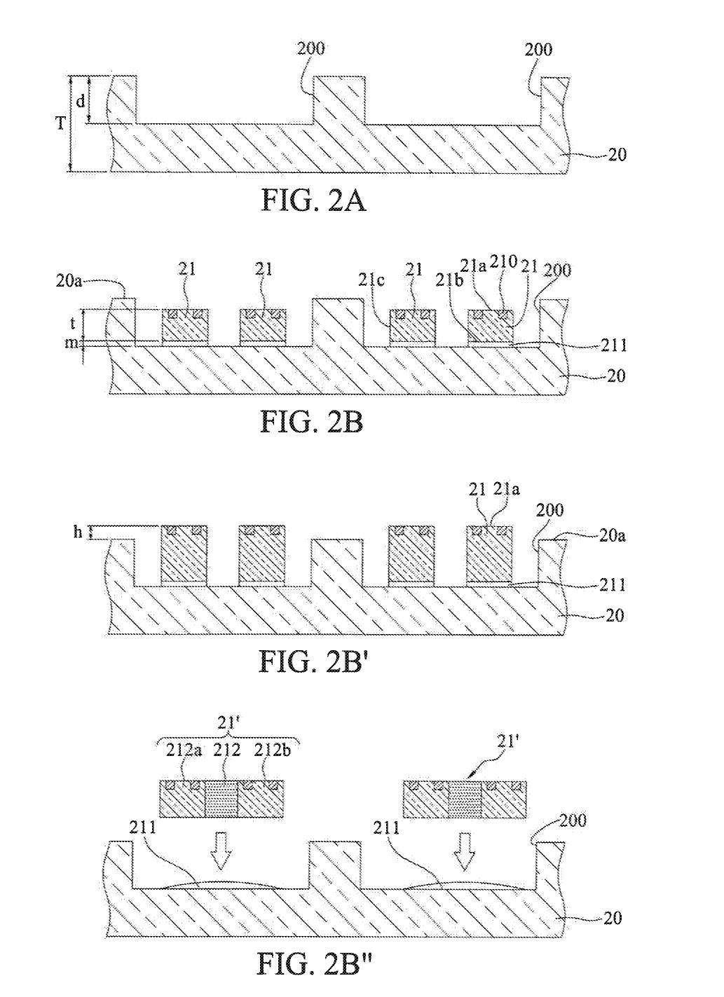

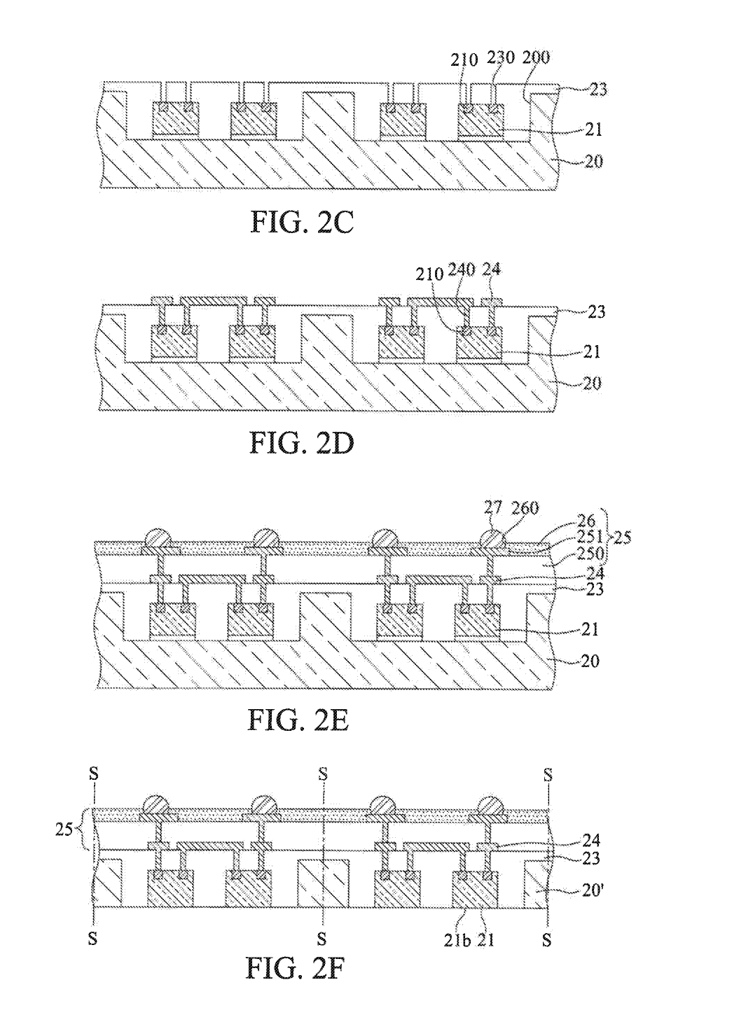

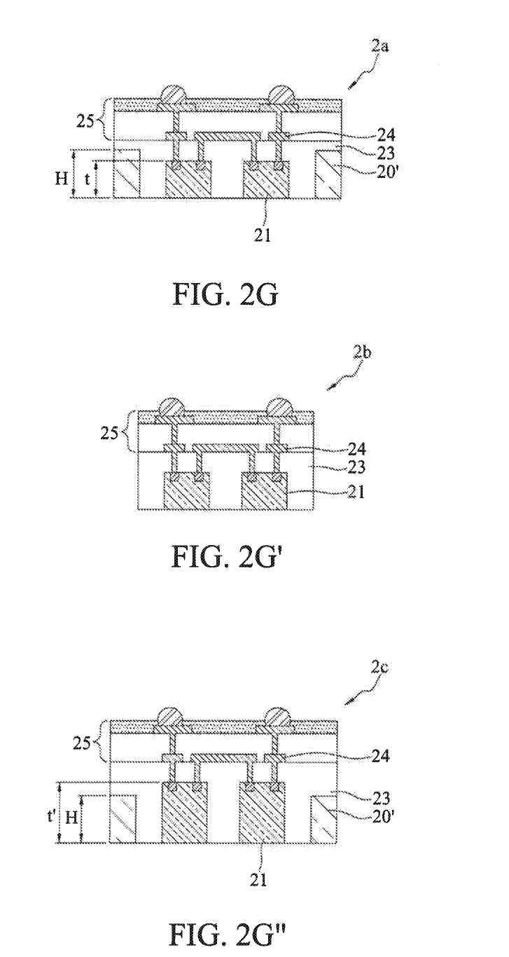

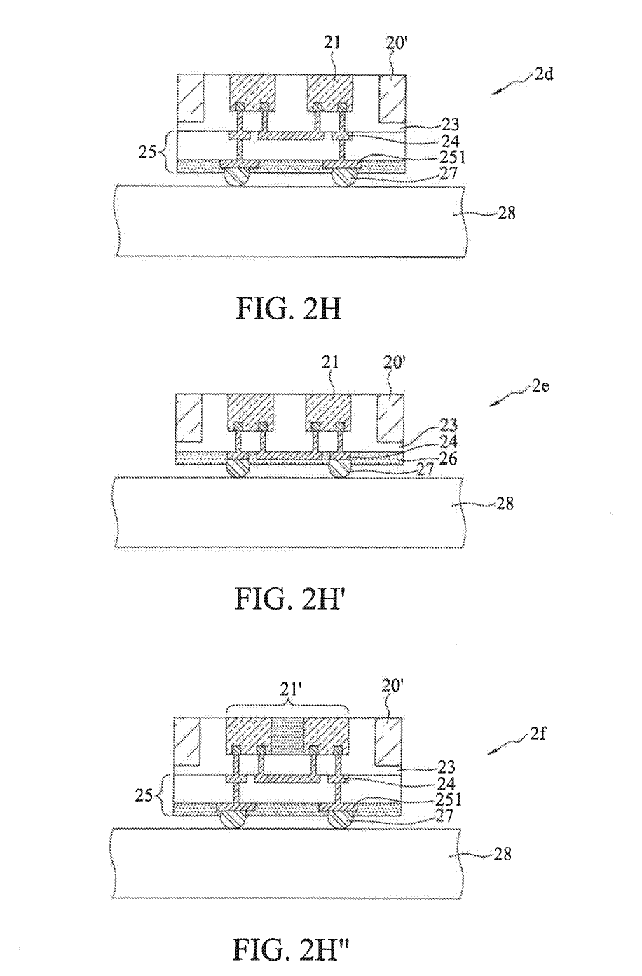

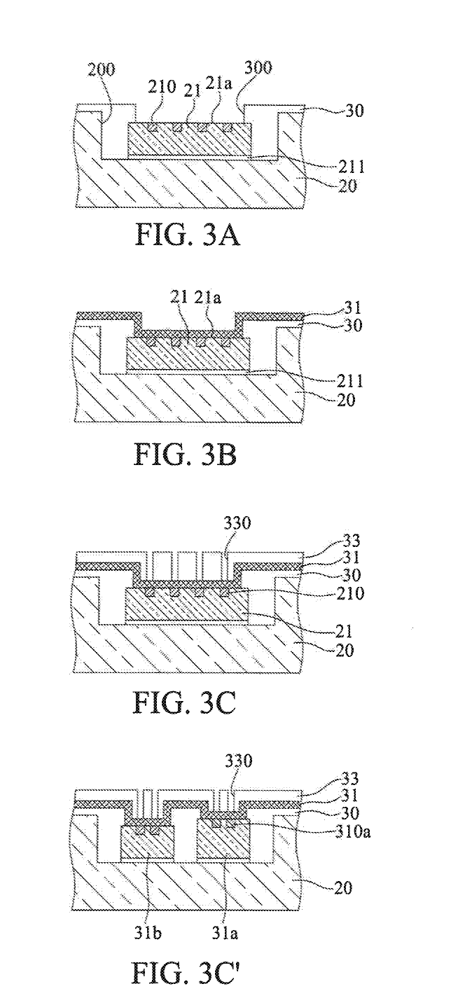

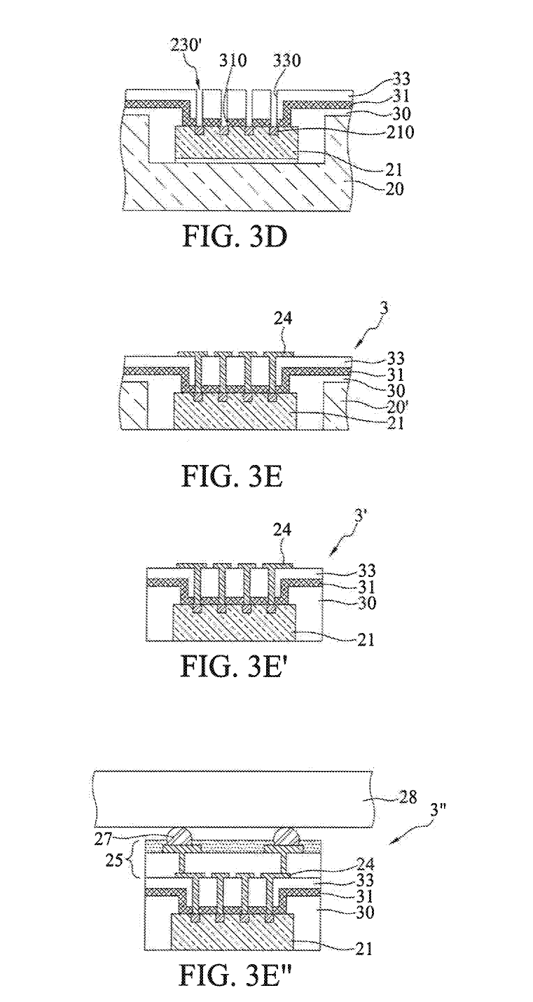

FIGS. 2A-2H are schematic cross-sectional views showing a method of fabricating a semiconductor package 2a-2f in accordance with a first embodiment of the present invention.

As shown in FIG. 2A, a carrier 20 having a plurality of grooves is provided.

In an embodiment, the carrier 20 is a silicon-containing board. The depth (d) of the groove 200 is a half of the thickness (T) of the carrier 20.

As shown in FIG. 2B, a plurality of semiconductor elements 21 are placed in the groove 200 of the carrier 20.

In an embodiment, the semiconductor element 21 has opposing active surface 21a and non-active surface 21b, and side surfaces 21a abutting the active surface 21a and the non-active surface 21b. A plurality of electrode pads 210 are formed on the active surface 21a. Through the non-active surface 21b, the semiconductor element 21 is assembled in the groove 200 via a bonding layer 211, allowing the active surface 21a of the semiconductor element 21 to be positioned lower than the surface 20a of the carrier 20, without protruding from the groove 200. The thickness (t) of the semiconductor element 21 is between 10 and 300 μm, preferably 20 to 150 μm. The thickness (m) of the bonding layer 211 is between 5 to 25 μm.

Moreover, the bonding layer 211 can be a die attach film (DAF), which can be formed on the non-active surface 21b of the semiconductor element 21, then the semiconductor element 21 is placed in the groove 200. Alternatively, the bonding layer can be formed in the groove 200 (using a dispensing process shown in FIG. 2B″), followed by attaching the semiconductor element 21 in the groove via the bonding layer 211.

In other embodiments, as shown in FIG. 2B′, the semiconductor element 21 protrudes the groove 200, i.e., the active surface 21a of the semiconductor element 21 is positioned higher than the surface 20a of the carrier 20 to form a height difference (h).

In an embodiment, the semiconductior eoement is a single-chip structure, such as having two semiconductor elements 21 placed in a groiove 200. However, the number of semiconductor elements placed in the groove is not limited by two. In other embodiments, as shown in 2B″, the semiconductor element 21′ can be a multichip module. For example, two chips 212a and 212b are bonded together with the bonding material 212 (epoxy resin) to form a module which is then placed in the groove.

As shown in FIG. 2C, following the process described in FIG. 2B, a dielectric layer 23 is formed on the carrier 20, the adhesive material 22, and the active surface 21a of the semiconductor element 21, with a plurality of vias 230 to expose the electrode pads 210 from the vias 230,

In an embodiment, the groove 200 is filled with the dielectric layer 23.

In an embodiment, the dielectric layer 23 is made of a non-organic material such as silicon oxide (SiO₂) or silicon nitride (SiₓN_{y}) or an organic material such as Polyimide (PI), Polybenzoxazole (PBO), or Benzocyclclobutene (BCB). The dielectric layer 23 and the adhesive material 22 are made of different materials.

In addition, vias 230 can be formed using chemical reactions (such as etching) or physical methods (such as laser).

As shown in FIG. 2D, a circuit layer 24 is formed on the dieelctric layer 23, to form the conductive blid vias 240 in the vias 230, allowing the circuit layer 24 to be electrically conneceted with the electrode pads 210 of the active surface 21a of the semiconductor element 21 through the conductive vias 240.

In an embodiment, the circuit layer 24 is a wafer level circuit, not packaging substrate level circuit. The minimal width and spacing of the circuits for packaging substrate is 12 μm but the semiconductor process, it is possible to fabricate circuits below 3 μm in terms of width and spacing. In an embodiment, since the carrier 20 is made of a silicon-containing material, the heat expansion coefficient thereof is similar to that of the semiconductor element 21. Therefore, it is possible to prevent the occourance of warpage of the carrier 20 leading to breakage of the semiconductor element 21, resulted from tempearture shift during fabricating process, so as to prevent mismatch between the conductive vias 240 and the electrode pads 210.

As shown in FIG. 2E, a redistribution lyer 25 is formed (RDL process) on the dielectric layer 23 and the circuit layer 24 and electrically connected with the circuit layer 24.

In an embodiment, the redistribution layer 24 comprises stacked dielectric part 250, circuit part 251 and insulative protective layer 26. The insulative protective layer 26 has a plurality of openings 260, allowing the circuit part 251 to be exposed from the openings 260, for the conductive elements 27 to be bonded thereon.

Moreover, the dielectric layer 250 is made of a non-organic material such as silicon oxide (SiO₂) or silicon nitride (SiₓN_{y} an organic material such as Polyimide (PI), Polybenzoxazole (PBO), or Benzocyclclobutene (BCB).

As shown in FIG. 2F, the first portion of the carrier below the groove 200 and the bonding layer 211 is removed to expose the non-active surface 21b of the semiconductor element and the adhesive matieral, so as to keep the second of the carrier on the side wall of the groove 200 intact, for the second portion to function as a supporting part 20′.

In an embodiment, the supporting part 20′ is a frame, and the thickness (t) of the semiconductor element 21 is not greater than the height (H) of the supporting part 20′. In another example, the thickness (t′) of the semiconductor element 21 is greater than the height (H) of the supporting part 20′.

In an embodiment, the non-organic material is silicon oxide (SiO₂) or silicon nitride (SiₓN_{y}), and the organic material is Polyimide (PI), Polybenzoxazole (PBO), or Benzocyclclobutene (BCB).

In summary, since it is no longer required to have a silicon interposer in the semiconductor package according to the present inventionas, the overall fabricating cost is significantly reduced, and the fabricating process is simpified, ensuring the productivity and yield of the final semiconductor package to be significantly improved.

Moreover, since there is no silicon interposer in the semiconductor package according to the present invention, the overall thickness of the final product is much reduced, allowing the semiconductor element to operation faster.

In addition, since the carrier is made of a silicon-containing material, the carrier is less likely to suffer from warpage.

Moreover, the supporting part is able to increase the strength of the overall structure of the semiconductor package.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor package, comprising:
a semiconductor element having opposing active and non-active surfaces;
a dielectric layer formed on the active surface of the semiconductor element;
a circuit layer formed on the dielectric layer and electrically connected to the semiconductor element.

2. The semiconductor package of claim 1, wherein the semiconductor element is a multi-chip module or a single-chip package.

3. The semiconductor package of claim 1, wherein the semiconductor element is between 10 to 300 μm in thickness.

4. The semiconductor package of claim 1, wherein the circuit layer has a plurality of conductive vias for being electrically connected with the semiconductor element.

5. The semiconductor package of claim 1, wherein the dielectric layer is made of a non-organic material or an organic material.

6. The semiconductor package of claim 5, wherein the non-organic material is silicon oxide (SiO₂) or silicon nitride (SiₓN_{y}).

7. The semiconductor package of 5, wherein the organic material is Polyimide (PI), Polybenzoxazole (PBO), Benzocyclclobutene (BCB).

8. The semiconductor package of claim 1, further comprising a redistribution layer formed on the dielectric layer and the circuit layer and electrically connected with the circuit layer.

9. The semiconductor package of claim 8, wherein the redistribution layer comprises stacked dielectric part and circuit part.

10. The semiconductor package of claim 9, wherein the dielectric layer is made of a non-organic material or an organic material.

11. The semiconductor package of claim 10, wherein the non-organic material is silicon oxide (SiO₂) or silicon nitride (SiₓN_{y}).

12. The semiconductor package of 10, wherein the organic material is Polyimide (PI), Polybenzoxazole (PBO), or Benzocyclclobutene (BCB).

13. The semiconductor package of claim 8, further comprising a substrate formed on and electrically connected to the redistribution layer.

14. The semiconductor package of claim 1, further comprising a substrate formed on and electrically connected to the circuit layer.

15. The semiconductor package of claim 1, wherein the semiconductor element further comprises side surfaces abutting the active surface and the non-active surface, and the dielectric layer covers a periphery of the side surfaces of the semiconductor package.

16. The semiconductor package of claim 15, further comprising a supporting part surrounding the dielectric layer.

17. The semiconductor package of claim 16, wherein the supporting part is a silicon-containing frame.

18. The semiconductor package of claim 16, wherein the supporting part has a height greater than a thickness of the semiconductor element.

19. The semiconductor package of claim 16, wherein the semiconductor element has a thickness greater than a height of the supporting part.

20. The semiconductor package of claim 1, further comprising an etch-stop layer formed between the active surface of the semiconductor element and the dielectric layer.

21. The semiconductor package of claim 20, the etch-stop layer is made of silicon nitride.

22. The semiconductor package of claim 20, further comprising a dielectric material covering the semiconductor element and having an opening exposing the semiconductor element, allowing the etch-stop layer to be formed between the active surface of the semiconductor element and the dielectric layer.

23. The semiconductor package of claim 22, wherein the dielectric layer is made of a non-organic material organic material.

24. The semiconductor package of claim 23, wherein the non-organic material is silicon oxide (SiO₂) or silicon nitride (SiₓN_{y}).

25. The semiconductor package of 23, wherein the organic material is Polyimide (PI), Polybenzoxazole (PBO), or Benzocyclclobutene (BCB).

26. The semiconductor package of claim 1, further comprising a supporting part surrounding the dielectric material.

27. The semiconductor package of claim 26, wherein the supporting part is a silicon-containing frame.

28. The semiconductor package of claim 26, wherein the supporting part has a height greater than a thickness of the semiconductor element.

29. The semiconductor package of claim 26, wherein the semiconductor element has a thickness greater than a height of the supporting part.

30. A method of fabricating a semiconductor package, comprising:
placing in a groove of a carrier a semiconductor element having opposing active and non-active surfaces;
forming a dielectric layer on the active surface of the semiconductor element;
forming on the dielectric layer a circuit layer electrically connected to the semiconductor element; and
removing a first portion of the carrier below the groove to keep a second portion of the carrier on a sidewall the groove intact for the second portion to function as a supporting part.

31. The method of claim 30, wherein the carrier is a silicon-containing board.

32. The method of claim 30, wherein the carrier is formed with a plurality of the grooves, and a singulation process is performed after the first portion of the carrier below the grooves is removed.

33. The method of claim 32, wherein the supporting part is also removed during the singulation process.

34. The method of claim 30, wherein the groove has a depth less than a half of a thickness of the carrier.

35. The method of claim 30, wherein the semiconductor element is a multi-chip module or a single-chip package.

36. The method of claim 30, wherein the semiconductor element is between 10 to 300 μm in thickness.

37. The method of claim 30, wherein the semiconductor element does not protrude from the groove.

38. The method of claim 30, wherein the semiconductor element protrudes from the groove.

39. The method of claim 30, wherein the non-active surface of the semiconductor element is bonded to the groove via a bonding layer.

40. The method of claim 39, wherein the bonding layer is between 5 to 25 μm in thickness.

41. The method of claim 39, wherein the bonding layer is also removed when the first portion of the carrier below the groove.

42. The method of claim 30, wherein the dielectric layer is made of a non-organic material or an organic material.

43. The method of claim 42, wherein the non-organic material is silicon oxide (SiO₂) or silicon nitride (SiₓN_{y}).

44. The method of claim 42, wherein the organic material is Polyimide (PI), Polybenzoxazole (PBO), or Benzocyclclobutene (BCB).

45. The method of claim 30, wherein the groove is filled with the dielectric layer.

46. The method of claim 30, wherein the semiconductor element further comprises side surfaces abutting the active surface and the non-active surface, and the dielectric layer covers a periphery of the side surfaces.

47. The method of claim 30, wherein the circuit layer has a plurality of conductive vias for being electrically connected to the semiconductor element.

48. The method of claim 30, further comprising a redistribution layer formed on the dielectric layer and the circuit layer, and electrically connected with the circuit layer.

49. The method of claim 48, wherein the redistribution layer comprises stacked dielectric part and circuit part.

50. The method of claim 49, wherein the dielectric layer is made of a non-organic material or an organic material.

51. The method of claim 50, wherein the non-organic material is silicon oxide (SiO₂) or silicon nitride (SiₓN_{y}).

52. The method of claim 50, wherein the organic material is Polyimide (PI), Polybenzoxazole (PBO), or Benzocyclclobutene (BCB).

53. The method of claim 48, further comprising, after removing the first portion of the carrier below the groove, bonding and electrically connecting a substrate to the redistribution layer.

54. The method of claim 30, further comprising, after removing the first portion of the carrier below the groove, bonding and electrically connecting a substrate to the circuit layer.

55. The method of claim 30, further comprising, prior to forming the dielectric layer, forming an etch-stop layer on the active surface of the semiconductor element, allowing the dielectric layer to be formed on the etch-stop layer.

56. The method of claim 55, wherein the etch-stop layer is made of silicon nitride.

57. The method of claim 55, further comprising, prior to forming the etch-stop layer, forming a dielectric material in the groove to cover the semiconductor element, and forming an opening on the dielectric material to expose the active surface of the semiconductor element, allowing the etch-stop layer to be formed on the active surface of the semiconductor element.

58. The method of claim 57, wherein the dielectric layer is made of a non-organic material or an organic material.

59. The method of claim 58, wherein the non-organic material is silicon oxide (SiO₂) or silicon nitride (SiₓN_{y}).

60. The method of claim 58, wherein the organic material is Polyimide (PI), Polybenzoxazole (PBO), or Benzocyclclobutene (BCB).
